(19) United States
(12) Patent Application Publication
(10) Pub. No.: US 2024/0250048 A1
(43) Pub. Date: Jul. 25, 2024

(54) ELECTRONIC COMPONENT

(71) Applicant: TDK CORPORATION, Tokyo (JP)

(72) Inventors: Kosuke TANAKA, Tokyo (JP); Masato SATO, Tokyo (JP); Kenta ONO, Tokyo (JP); Takashi WATANABE, Tokyo (JP)

(73) Assignee: TDK CORPORATION, Tokyo (JP)

(21) Appl. No.: 18/561,435

(22) PCT Filed: Mar. 25, 2022
(86) PCT No.: PCT/JP2022/014607

§ 371 Date: Nov. 16, 2023

(30) Foreign Application Priority Data
May 20, 2021 (JP) 2021-085508

(51) Int. Cl. H01L 23/00; H01L 23/29; H01L 23/31

(52) U.S. Cl. CPC H01L 24/05; H01L 23/291; H01L 23/3171; H01L 24/03; H01L 23/293; H01L 2224/0345; H01L 2224/03462; H01L 2224/05007; H01L 2224/05017; H01L 2224/05018; H01L 2224/05083; H01L 2224/05147; H01L 2224/05155; H01L 2224/05557; H01L 2224/05558; H01L 2224/05573; H01L 2224/05644; H01L 2924/365; H01L 2924/381

(57) ABSTRACT

In the electronic component, the second portion of the diffusion prevention layer extends parallel to the main surface of the base material. When the electronic component is surface-mounted on the mounting substrate, the conductive bonding material such as solder is interposed between the electrodes of the electronic component and the land electrodes of the mounting substrate. In the case that the bonding surface between the diffusion prevention layer and the substrate is wide, it is difficult for the metal component of the bonding material to reach the body portion of the electrodes through the bonding surface. Therefore, a situation in which metal component of the bonding material diffuse into the body portion is suppressed, and a decrease in strength of the electrodes due to the diffusion is suppressed.

### TECHNICAL FIELD

The present disclosure relates to an electronic component.

### BACKGROUND ART

When an electronic component such as a semiconductor element is mounted on a mounting substrate, good bonding between pad electrodes of the electronic component and land electrodes of the mounting substrate is required. In the case that a bonding failure occurs between the pad electrodes of the electronic component and the land electrodes of the mounting substrate, in addition to an increase in contact resistance, the electronic component is easily detached from the mounting substrate due to vibration or the like, and thus reliability is reduced.

As one of techniques for mounting the electronic component on the mounting substrate, a surface mounting technique is known (for example, Patent Literature 1 below). In the surface mounting technique, each pad on the electronic component mounted on the mounting substrate and each land electrode of the mounting substrate are aligned with each other, and both are bonded via a conductive bonding material such as solder.

### CITATION LIST

### Patent Literature

Patent Literature 1: Japanese Patent Application Publication No. 2013-45843

### SUMMARY OF INVENTION

### Technical Problem

In the above-described surface mounting technique, when the metal component of the bonding material diffuses into the pad electrode and/or the land electrode, there is a concern that desired strength may not be realized, and it is difficult to realize sufficient reliability.

An object of one aspect of the present disclosure is to provide an electronic component with improved reliability.

### Solution to Problem

A electronic component according to one aspect of the present disclosure includes a base material having an insulating film constituting a main surface, and a thick-film electrode provided on the main surface of the base material, the thick-film electrode including a body portion located above the main surface, a conduction portion extending from the body portion toward the base material and penetrating the insulating film, and a diffusion prevention layer covering the body portion, wherein the diffusion prevention layer has a first portion directly covering a surface of the body portion and a second portion directly covering the main surface in a peripheral region of the body portion and extends parallel to the main surface.

In the above-described electronic component, since the second portion of the diffusion prevention layer extends parallel to the main surface of the base material, the bonding surface between the diffusion prevention layer and the base material is enlarged. Therefore, when the electronic component is surface-mounted on the mounting substrate, it is difficult for the metal component of the bonding material interposed between the thick-film electrode of the electronic component and the land electrode of the mounting substrate to reach the body portion of the thick-film electrode, and a decrease in strength of the thick-film electrode due to diffusion is suppressed.

In the electronic component according to another aspect, a dimension of the diffusion prevention layer in a portion covering the main surface of the base material is greater than a dimension of a thinnest portion of the diffusion prevention layer in a portion covering the body portion.

In the electronic component according to another aspect, a plurality of the thick-film electrodes are provided on the main surface of the base material, and t1<L<D/2 holds, where D is a distance between the thick-film electrodes adjacent to each other, t1 is a dimension of the diffusion prevention layer covering the body portion, and L is a dimension of the diffusion prevention layer covering the main surface of the base material.

### Advantageous Effects of Invention

According to various aspects of the present disclosure, an electronic component with improved reliability is provided.

### BRIEF DESCRIPTION OF DRAWINGS

FIG. 1 is a cross-sectional view showing the electronic component according to the embodiment.

FIG. 2 is an enlarged view of a main part of the electronic component of FIG. 1.

FIG. 3 is a view showing a step in manufacturing the electronic component of FIG. 1.

FIG. 4 is a view showing a step in manufacturing the electronic component of FIG. 1.

FIG. 5 is a view showing a step in manufacturing the electronic component of FIG. 1.

FIG. 6 is a view showing a step in manufacturing the electronic component of FIG. 1.

### DESCRIPTION OF EMBODIMENTS

Hereinafter, embodiments of the present disclosure will be described with reference to the accompanying drawings. In the description of the drawings, the same or equivalent elements are denoted by the same reference numerals, and redundant description is omitted.

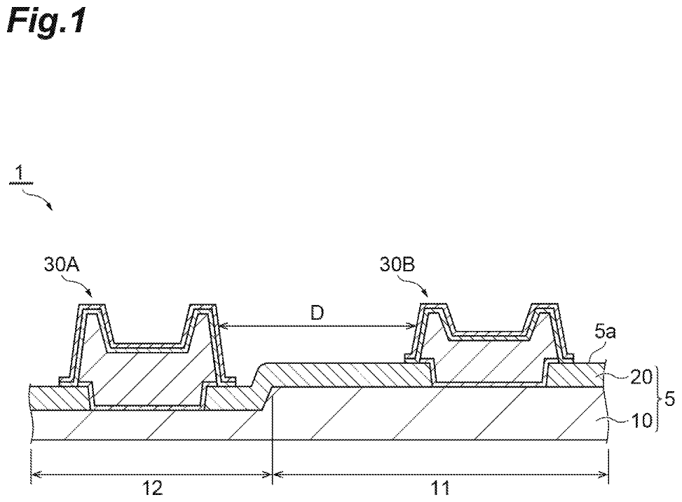

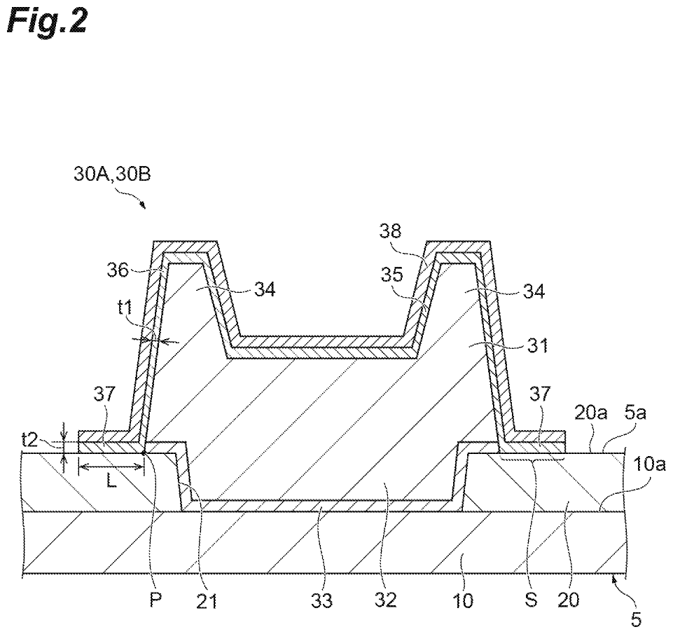

A configuration of an electronic component according to the embodiment will be described with reference to FIGS. 1 and 2. The electronic component 1 according to the embodiment includes a base material 5 and a pair of electrodes 30A and 30B. The electronic component 1 is, for example, a semiconductor element such as an LED element or a semiconductor laser element.

The base material 5 includes a substrate 10 and an insulating film 20, and has a main surface 5a.

The substrate 10 has a flat main surface 10a. In the present embodiment, the main surface 10a is composed of a semiconductor layer.

The insulating film 20 covers the main surface 10a of the substrate 10. The insulating film 20 is a so-called passivation film. The insulating film 20 is made of an oxide or a nitride containing at least one element selected from the group consisting of Si, Al, Zr, Mg, Ta, Ti, and Y, or a resin. The insulating film 20 has a substantially uniform thickness T in a first region 11 and a second region 12 of the main surface 10a. A through-hole 21 is provided in the insulating film 20. In the present embodiment, the through-hole 21 has a circular shape with a diameter D1 when viewed from a direction perpendicular to the main surface 10a.

Each of the pair of electrodes 30A and 30B is made of a metal material, and is made of Cu in the present embodiment. Each of the electrodes 30A and 30B is a thick-film electrode (pad electrode) provided on the main surface 5a of the base material 5 and extending in the normal direction of the main surface 10a of the substrate 10. Each of the electrodes 30A and 30B includes a body portion 31 and a conduction portion 32. The body portion 31 is a portion located above the insulating film 20. In the present embodiment, the body portion 31 has a square shape when viewed from the direction perpendicular to the main surface 10a. The conduction portion 32 is a portion extending from the body portion 31 toward the base material 5, and extends through the through-hole 21 of the insulating film 20 to reach the substrate 10. In the present embodiment, the conduction portion 32 is provided so as to completely fill the through-hole 21 of the insulating film 20. Therefore, in the present embodiment, the conduction portion 32 has a cylindrical shape with the diameter D1.

The body portion 31 and the conduction portion 32 of the electrodes 30A and 30B can be formed by electrolytic plating of Cu. In this case, each of the electrodes 30A and 30B includes the electrode film 33. The electrode film 33 may be made of a metal material such as Cu. The electrode film 33 integrally covers the substrate 10 and the insulating film 20. More specifically, the electrode film 33 integrally covers the main surface 5a of the base material 5 (that is, the edge of the through-hole 21 in an upper surface 20a of the insulating film 20 and the main surface 10a of the substrate 10 exposed from the through-hole 21) and the side surface of the through-hole 21.

In the present embodiment, the body portion 31 of each electrode 30A and 30B further comprises a raised portion 34. The raised portion 34 is a portion raised from the upper surface 30a of the body portion 31, and is formed in an annular region corresponding to the edge of the through-hole 21 of the insulating film 20.

Each of the electrodes 30A and 30B further includes a diffusion prevention layer 35 covering the body portion 31. The diffusion prevention layer 35 is a layer for preventing metal components (Cu in the present embodiment) of the electrodes 30A and 30B from diffusing into a conductive bonding material such as solder. The diffusion prevention layer 35 can be made of a material containing at least one of Ni, Ta, Ti, W, Mo, Cr, Zn, In, Nb, Sn, and C. The diffusion prevention layer 35 can be formed by sputtering deposition, for example. The diffusion prevention layer 35 may be a single layer or may be a multi-layer. In the present embodiment, the diffusion prevention layer 35 is formed of a Ni layer that directly covers the body portion 31.

The diffusion prevention layer 35 has a first portion 36 that directly covering the surface of the body portion 31 and a second portion 37 directly covering the main surface 5a of the base material 5 in the peripheral region of the body portion 31. The first portion 36 and the second portion 37 of the diffusion prevention layer 35 are continuously formed. In the diffusion prevention layer 35, the first portion 36 and the second portion 37 are switched at the outer periphery of the body portion 31 (point P in the cross section of FIG. 2) on the main surface 5a of the base material 5 (more specifically, the upper surface 20a of the insulating film 20). The second portion 37 extends parallel to the main surface 5a of the base material 5. As shown in FIG. 2, in the diffusion prevention layer 35 formed by sputtering, the first portion 36 may be thinner in a portion extending along the normal direction of the main surface 10a of the substrate 10 (for example, a portion covering the side surface of the raised portion 34 of the body portion 31) than in a portion parallel to the main surface 5a of the base material 5 (for example, a portion covering the top of the raised portion 34 of the body portion 31 or a portion covering a valley portion between the raised portions 34). In this case, the first portion 36 is the thinnest (thickness t1) in a portion extending in the direction along the normal direction of the main surface 10a of the substrate 10. In the present embodiment, the thickness t2 of the second portion 37 of the diffusion prevention layer 35 (i.e., the height with respect to the main surface 5a of the base material 5) is greater than the thinnest portion with thickness t1 of the first portion 36 (t2>t1).

Each of the electrode 30A and 30B further comprises an antioxidation layer 38. The antioxidation layer 38 directly covers the diffusion prevention layer 35 and prevents oxidation of the diffusion prevention layer 35. The antioxidation layer 38 may be formed of an Au layer. By preventing the surface of the diffusion prevention layer 35 (that is, the Ni layer) from being oxidized by Au constituting the antioxidation layer 38, wettability of the diffusion prevention layer 35 with respect to the conductive bonding material such as solder is improved, and a bonding structure having higher reliability is obtained.

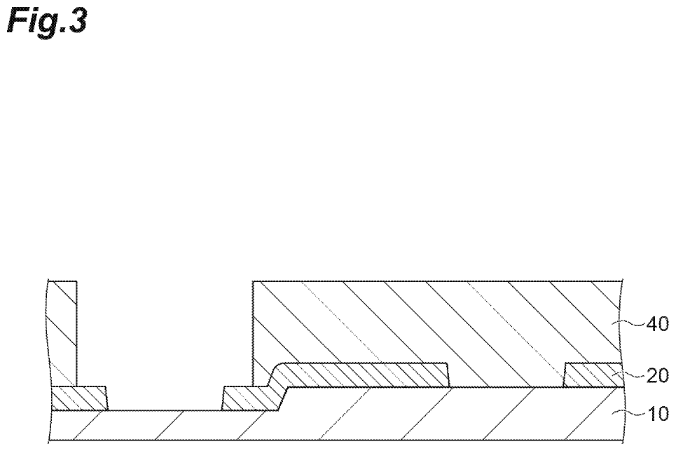

Next, a procedure for manufacturing the above-described electronic component 1 will be described with reference to FIGS. 3 to 6.

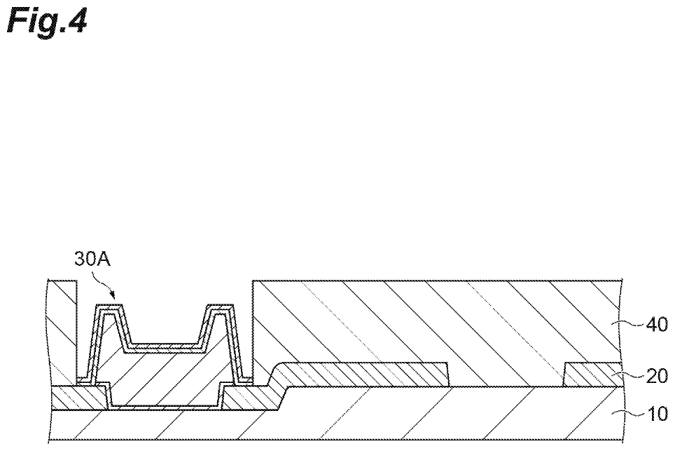

When the electronic component 1 is manufactured, firstly, one electrode 30A is provided on the substrate 10 as shown in FIGS. 3 and 4. FIG. 3 shows a step of forming a thick-film resist 40 by lift-off exposing a region where the electrode 30A is to be formed on the insulating film 20 patterned on the main surface 10a of the substrate 10. FIG. 4 shows a step of forming the electrode 30A in the region exposed from the thick-film resist 40. The electrode 30A is provided by forming the electrode film 33 by sputtering, then forming the conduction portion 32 and the body portion 31 by electrolytic plating using the electrode film 33, and further forming the diffusion prevention layer 35 and the antioxidation layer 38 by sputtering Ni and Au in this order.

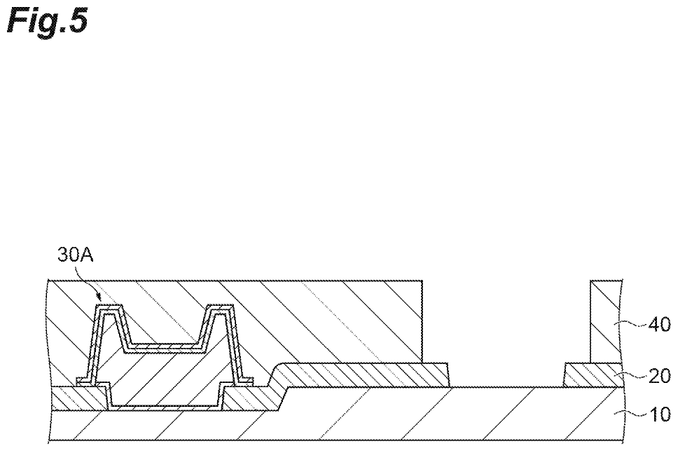

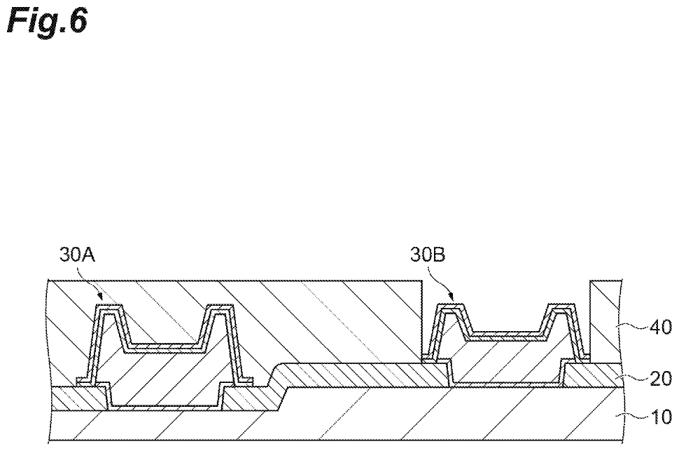

Subsequently, as shown in FIGS. 5 and 6, the other electrode 30B is provided on the substrate 10. FIG. 5 shows a step of exposing by lift-off a region of the thick-film resist 40 where the electrode 30B is to be formed. FIG. 6 shows a step of forming the electrode 30B in the region exposed from the thick-film resist 40. Similarly to the electrode 30A, the electrode 30B is provided by forming the electrode film 33 by sputtering, forming the conduction portion 32 and the body portion 31 by electrolytic plating using the electrode film 33, and forming the diffusion prevention layer 35 and the antioxidation 38 by sputtering Ni and Au in this order.

In the electronic component 1 described above, the second portion 37 of the diffusion prevention layer 35 extends in parallel to the main surface 5a of the base material 5. Therefore, the bonding surface (bonding surface S in FIG. 2) between the diffusion prevention layer 35 and the substrate 10 is enlarged.

When the electronic component 1 is surface-mounted on the mounting substrate, the conductive bonding material such as solder is interposed between the electrodes 30A and 30B of the electronic component 1 and the land electrodes of the mounting substrate. In the case that the bonding surface between the diffusion prevention layer 35 and the substrate 10 is wide, it is difficult for the metal component of the bonding material to reach the body portion 31 of the electrodes 30A and 30B through the bonding surface S.

Therefore, in the electronic component 1, a situation in which the metal component of the bonding material diffuses into the body portion 31 is suppressed, and thus a decrease in strength of the electrodes 30A and 30B due to the diffusion is suppressed.

In addition, in the electronic component 1, for suppressing the diffusion by the diffusion prevention layer 35, the thickness (dimension) of the diffusion prevention layer 35 can be set to a predetermined thickness or more. The thickness t2 of the second portion 37 of the diffusion prevention layer 35 may be designed to be greater than the thickness t1 of the first portion 36. By designing the thinnest portion (thickness t1) of the first portion 36 to be thick enough to prevent diffusion, diffusion can be prevented even in the second portion 37 having thickness t2 thicker than t1, and diffusion into the body portion 31 is more reliably suppressed.

Furthermore, the electronic component 1 is designed to satisfy t1<L<D/2, where D is the distance between adjacent electrodes 30A and 30B, t1 is the thickness of the first portion 36 of the diffusion prevention layer 35, and L is the length (dimension) of the second portion 37 in the direction parallel to the main surface 5a of the base material 5. In order for the diffusion prevention layer 35 to suppress diffusion and to increase adhesion between the diffusion prevention layer 35 and the insulating film 20, the second portion 37 may have a predetermined length L or more. Further, in order to avoid a short circuit between the adjacent electrodes 30A and 30B, the length L of the second portions 37 can be set shorter than half of the distance D between the electrodes 30A and 30B.

Although the embodiments of the present disclosure have been described above, the present disclosure is not necessarily limited to the above-described embodiments, and various modifications can be made without departing from the scope of the present disclosure.

For example, the formation of the electrode is not limited to electroplating, and may be electroless plating, or may be another film formation method (for example, sputtering deposition). Further, the cross-sectional shape of the through-hole provided in the insulating film is not limited to a circular shape, and may be a polygonal shape such as a quadrangular shape or an elliptical shape. The shape of the body portion of the electrode is not limited to a square shape and may be a circular shape, a polygonal shape, or an elliptical shape when viewed from the direction perpendicular to the main surface of the substrate.

### REFERENCE SIGNS LIST

1 electronic component
5 base material
5a main surface
10 substrate
20 insulating film
30A and 30B electrode
35 diffusion prevention layer
36 first portion
37 second portion

1. An electronic component comprising:
a base material having an insulating film constituting a main surface; and
a thick-film electrode provided on the main surface of the base material, the thick-film electrode including a body portion located above the main surface, a conduction portion extending from the body portion toward the base material and penetrating the insulating film, and a diffusion prevention layer covering the body portion,
wherein the diffusion prevention layer has a first portion directly covering a surface of the body portion and a second portion directly covering the main surface in a peripheral region of the body portion and extends parallel to the main surface.

2. The electronic component according to claim 1, wherein a dimension of the diffusion prevention layer in a portion covering the main surface of the base material is greater than a dimension of a thinnest portion of the diffusion prevention layer in a portion covering the body portion.

3. The electronic component according to claim 1, wherein a plurality of the thick-film electrodes are provided on the main surface of the base material, and
wherein t1<L<D/2 holds, where D is a distance between the thick-film electrodes adjacent to each other, t1 is a dimension of the diffusion prevention layer covering the body portion, and L is a dimension of the diffusion prevention layer covering the main surface of the base material.

4. The semiconductor element according to claim 3, wherein the insulating film has a substantially uniform thickness in the thick-film electrodes-forming regions.

5. The semiconductor element according to claim 1, wherein the insulating film is made of an oxide or a nitride containing at least one element selected from the group consisting of Si, Al, Zr, Mg, Ta, Ti, and Y, or a resin.

6. The semiconductor element according to claim 1, wherein the body portion of the thick-film electrode has a raised portion raised from the surface of the body portion opposite to the surface on the base material side and formed in an annular region corresponding to an edge of a through-hole of the insulating film penetrated by the conduction portion.

7. The semiconductor element according to claim 1, wherein the diffusion prevention layer is a single layer or a multi-layer.
